(19) United States
(12) Patent Application Publication
(10) Pub. No.: US 2021/0195814 A1
(43) Pub. Date: Jun. 24, 2021

(54) ELECTRONIC DEVICES WITH EMI PROTECTION FILMS

(71) Applicant: Hewlett-Packard Development Company, L.P., Spring, TX (US)

(72) Inventors: Shih-Huang Wu, Spring, TX (US); Kuan-Ting Wu, Taipei (TW)

(73) Assignee: Hewlett-Packard Development Company, L.P., Spring, TX (US)

(21) Appl. No.: 17/046,029

(22) PCT Filed: Sep. 14, 2018
(86) PCT No.: PCT/US2018/051005

§ 371 Date: Oct. 8, 2020

(51) Int. Cl. H05K 9/00

(52) U.S. Cl. CPC H05K 9/0024; H05K 9/0081

(57) ABSTRACT

The present disclosure is drawn to an electronic device including a substrate, an electronic component carried by the substrate, an EMI protection film over-molded on the electronic component, and an adhesive layer directly adhering the EMI protection film to the electronic component. The EMI protection film includes a ferromagnetic material.

### BACKGROUND

The use of electronic devices of all types continues to increase. Cellular phones, including smartphones, have become nearly ubiquitous. Tablet computers have also become widely used in recent years. Portable laptop computers continue to be used by many for personal, entertainment, and business purposes. Desktop computers, as well as other more sophisticated computing, storage, server, etc., electronic devices, are also in wide use. There are also other electronic devices that often include multiple electronic components in close proximity to one another, and/or which operate with wireless communication, sometimes with some difficulty due to spatial arrangements and other considerations.

### BRIEF DESCRIPTION OF THE DRAWING

FIG. 1 is a schematic cross-sectional view of an example electronic device with EMI protection film applied to electronic components in accordance with examples of the present disclosure;

FIGS. 2A-2C depict schematic views of an example assembly of layers for vacuum-release over-molding applications in accordance with examples of the present disclosure;

FIG. 3 is a flow chart depicting an example method protecting an electronic device from EMI in accordance with examples of the present disclosure; and

FIG. 4 is a flow chart depicting an example method of reducing EMI in an electronic device in accordance with examples of the present disclosure.

### DETAILED DESCRIPTION

Electromagnetic interference (EMI) protection layers as described herein can be applied or positioned on electronic components of laptops, tablets, mobile phones, etc., to absorb or otherwise prevent EMI to or from the electronic component to which that EMI protection film is applied. This can also improve antenna signal performance of other components of the electronic device that may be close enough in proximity where EMI may otherwise have a negative impact on performance, e.g., reduce or stop functionality. Currents and voltages can also be modified for electronic components to be more effective since the components are shielded for EMI interference (to or from the electronic component). This can also enhance wireless communication quality to a wide variety of wireless communication standard systems, such as cellular, Wi-Fi, Bluetooth®, radio, broadcast, satellite, etc. This can also provide benefits to nearby electrical devices, such as a mobile phone that is in close proximity to a desktop computer, laptop computer, tablet device. etc., e.g., EMI may negatively impact mobile phone wireless operation emitted from a laptop or tablet, or vice versa. As EMI can interrupt, obstruct, and in some cases, damage other electronic components, the EMI protection films described herein can enhance performance of underperforming electronics and in some cases, even prevent or ameliorate damage.

In accordance with this, the present disclosure is drawn to an electronic device including a substrate, an electronic component carried by the substrate, an EMI protection film over-molded on the electronic component, and an adhesive layer directly adhering the EMI protection film to the electronic component. In this example, the EMI protection film comprises a ferromagnetic material. The substrate can be, for example, a circuit board, an electronic device frame, or an electronic device housing. The electronic component can include, for example, a battery, a printed circuit board (PCB), a central processing unit CPU), a graphics processing unit (GPU), an integrated circuit (IC), a piezoelectric device, a cable assembly, a semiconductor, a display chip, a memristor, an electro-mechanical device, e.g., MEMS, an electro-optical device, a transducer, a sensor, a detector, an antenna, solid-state drive (SSD), or a combination thereof. In another example, a second electronic component carried that is also carried by the substrate can also include an EMI protection film over-molded thereon, either from a second EMI protection film or from a common EMI protection film. Again, an adhesive layer can directly adhere the EMI protection film to the electronic component. The EMI protection film, in one example, can be over-molded on the electronic component by vacuum-release over-molding. As the EMI protection film includes a ferromagnetic material, the EMI protection film can be magnetized with a magnetic flux density of about 4,000 Gauss to about 15,000 Gauss. The EMI protection film, for example, can include an iron-silicon alloy, an iron-silicon-chromium alloy, an iron-silicon-boron alloy, an oxide-based ferromagnet, a neodymium-iron-boron ferromagnet, a manganese- and zinc-based ferromagnet, a nickel- and zinc-based ferromagnet, a manganese-bismuth ferromagnet, an aluminum-copper-manganese ferromagnet, a neodymium-iron-boron ferromagnet, or a combination thereof. The EMI protection film can have an average thickness from about 0.05 mm to about 0.35 mm. In further detail regarding the adhesive layer, this layer can have a thickness from about 5 μm to about 50 μm. The adhesive layer can provide a layer of insulation between the EMI protection film and the electronic component. In further detail, the adhesive layer is photo-cured between the EMI protection layer and the electronic component. Regarding the electronic components, they may include an EMI susceptible portion, an EMI emitting portion, or both on a common substrate. In this example, the EMI protection film can be applied to the EMI susceptible portion, the EMI emitting portion, or both. In still further examples, in addition to the electronic component, the EMI protection film can be applied to the substrate as well in some instances.

In another example, a method of protecting an electronic device from EMI can include applying an adhesive layer to an EMI protection film or an electronic component, and vacuum-release over-molding the EMI protection film over an electronic component with the adhesive layer positioned between the EMI protection film and the electronic component. The adhesive layer can be photo-curable, e.g., UV-curable, and the adhesive layer can be exposed to UV energy at from about 600 mJ/cm² to about 1,500 mJ/cm² for about 5 seconds to about 1 minute.

In another example, a method of reducing EMI in an electronic device can include selecting an electronic component of an electronic device that is susceptible to EMI or emits EMI, e.g., the EMI is sufficient to reduce electronic device performance, and applying an EMI protection layer on the electronic component with an adhesive layer positioned directly between the electronic component and the EMI protection layer. In one example, applying can be by vacuum-release over-molding.

It is noted that when discussing either the electronics devices or the methods herein, such discussions can be considered applicable to one another whether or not they are explicitly discussed in the context of that example. Thus, for example, when discussing the EMI protection film in the context of one of the device examples, such disclosure is also relevant to and directly supported in the context of other device examples and method examples, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

In further detail, it is noted that the spatial relationship between layers is often described herein as positioned “on” or applied “on” another layer and does not infer that this layer is positioned directly on the layer to which it refers, but could have intervening layers therebetween. That being stated, a layer described as being positioned on another structure can be positioned directly on that other structure, and thus such a description finds support herein for being positioned directly on the referenced structure.

Electronic Devices

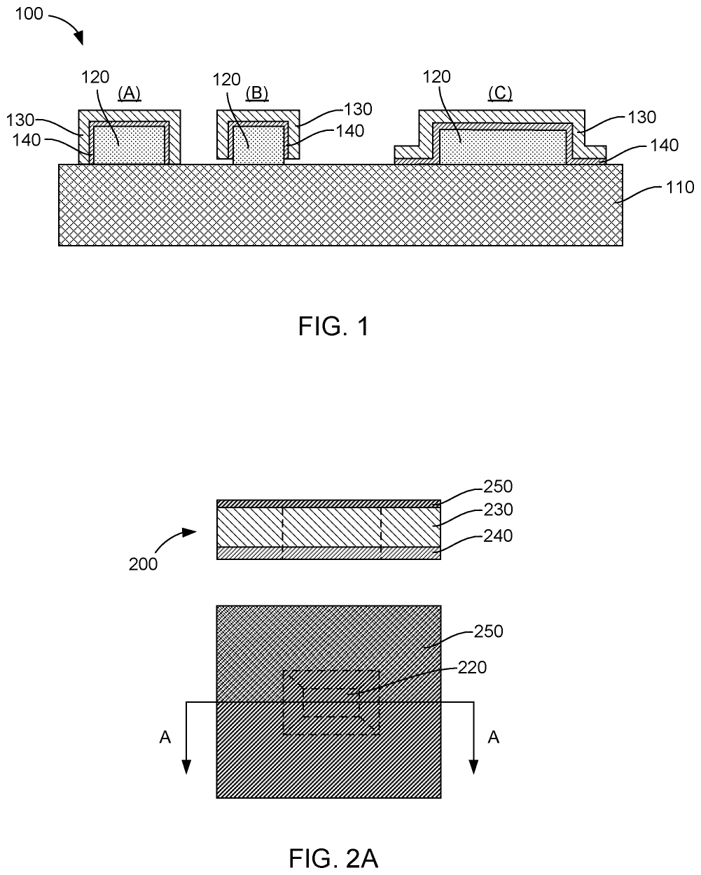

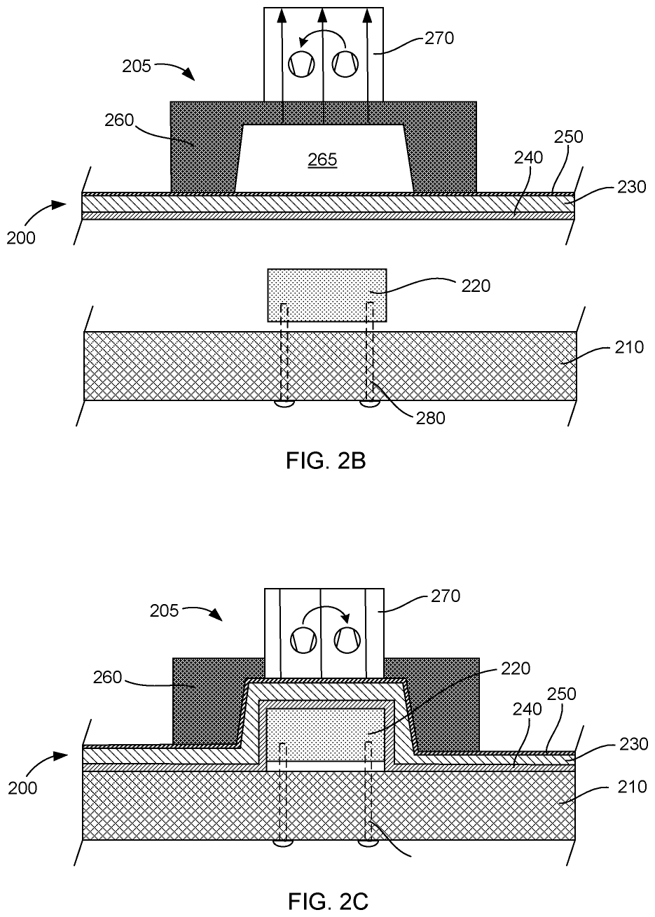

The present disclosure also extends to electronic devices of various types, such as laptop computers, tablets, mobile phones including smartphones, gaming systems, televisions, etc., that may include various electronic components, including these and other devices that may include wireless communication components and other components that may electromagnetically interact therewith. In one example, and as shown in FIG. 1, an electronic device 100 can include a substrate 110 with an electronic component 120 carried by the substrate. In this example, there are multiple electronic components shown, which can be, for example, a CPU, a printed circuit board, a battery, a GPU, an IC, etc. The substrate can be, for example, a circuit board support, e.g., wafer, an electronic device frame, e.g., chassis, or an electronic device housing, e.g., a laptop cover, a tablet cover, a mobile phone cover, or the like. In this example, the electronic components are shown schematically as rectangular blocks, but typically would be more complicated structures of assembled sub-components, for example. Also shown in FIG. 1, the electronic components are shown sitting directly on the substrate (or adhered to the substrate such as by an adhesive, not shown), but this may not be the arrangement in other examples, as the electronic component may be carried by the substrate with space between the substrate and the electronic components, such as that shown hereinafter in FIGS. 2B and 2C, for example. Whether applied directly on the substrate, positioned with an adhesive between the substrate and electronic component, or positioned on the substrate with fasteners that may suspend the electronic component above the substrate, the electronic component can be described as being “carried by” the substrate, or positioned “on” the substrate.

The electronic component(s) 120 can further have an EMI protection film 130 over-molded on the electronic component. The EMI protection film can include a ferromagnetic material. In some examples, the ferromagnetic material may remain unmagnetized. In other examples, the ferromagnetic material can be magnetized, such as at a magnetic flux density from about 4,000 Gauss to about 15,000 Gauss, or to other magnetic flux densities. The ferromagnetic material can have an average thickness, for example, of about 0.05 mm to about 0.35 mm, among others.

The EMI protection film 130 can be positioned on the electronic component 120 with an adhesive layer 140 therebetween with the adhesive material directly adhering the EMI protection film to the electronic component. The adhesive layer can act as an insulative layer between the electronic component and the EMI protection film. The adhesive layer can have an average thickness from about 5 μm to about 50 μm, from about 10 μm to about 40 μm, or from about 15 μm to about 35 μm, for example.

Also shown, the EMI protection film 130 can be positioned on the electronic component 120 in a manner that surrounds the electronic component but is not adhered to the substrate, as shown at (A), on a portion of the electronic component as shown at (B), or the EMI protection film can in some instances extend beyond the electronic component and onto the substrate 110, as shown at (C). If the EMI protection film comes into contact with the electronic component of the substrate without the adhesive layer therebetween, then those areas are typically areas that would not be negatively impacted by any conductive or semi-conductive properties of the EMI protection film, e.g., short-circuiting electronic components. In further detail, though not shown, in some examples, a common EMI protection layer (and adhesive layer) can be over-molded onto multiple electronic components.

Substrates

The substrate can be any support material that carries electronic components, including a circuit board support, e.g., wafer, an electronic device frame, e.g., chassis, or an electronic device housing, e.g., a laptop cover, a tablet cover, a mobile phone cover, or the like. The substrate is not particularly limited with respect to thickness. However, when used as an electronic device housing, casing, or panel; or when used to support circuitry, e.g., circuit board support, etc., common thicknesses can be from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used. When applied to an electronic device housing, such as a laptop or tablet cover for example, the substrate surface to which the electronic component is attached may be inward facing.

Electronic Components

The electronic components can be any electronic components that may be present in a desktop computer, laptop computer, tablet, mobile phone, gaming system, television, etc. Many electronic components that can be over-molded as described herein may be wireless communication components and/or other electronic components that may electromagnetically interact therewith. In one sense, an “electronic component” can be described as a discrete device in a more complex electronics system that effects electromagnetic energy in the form of electrons, e.g., current, voltage, etc., light, electromagnetic radiation, etc. Examples may include those with electrical terminals that connect to an electronic circuit that carries out a specific function, e.g., wireless transmitter/receiver, amplifier, oscillator, resistor, switch, etc. Electronic components can be packaged either discretely, or can be packaged as a system or network of multiple components. Thus, in referring to electronic “components,” this can include either individual electronic components as well as packages of component assemblies such as chips or circuit boards with multiple electrical systems or sub-systems. Thus, example electronic components as describe herein can include power sources, e.g., a battery, printed circuit boards (PCB), central processing units (CPU), graphics processing units (GPU), integrated circuits (IC), piezoelectric devices, cable assemblies, semiconductors, display chips, memristors, transducers, sensors, detectors, antennas, solid-state drive (SSD), etc. As this list indicates, electronic components (including individual discrete components or packaged components) can thus be active or passive, electro-mechanical, electro-optical, etc., without limitation. Furthermore, the electronic components described herein can be applied to or positioned on a substrate by any fastening approach available, including bonding directly to the substrate, fastening directly to the substrate, fastening indirectly to the substrate, fastening to the substrate with open space therebetween, fastening to the substrate without open space therebetween, etc.

EMI Protection Films

The electromagnetic interference (EMI) protection films, as described, can be applied to electronic components of an electronic device as a thin film. The film can have an average thickness from about 0.05 mm to about 0.35 mm, from about 0.1 mm to about 0.3 mm, or from about 0.15 mm to about 0.25 mm. The EMI protection film can be applied by vacuum-release over-molding as described hereinafter in more detail, for example. Furthermore, the EMI protection film can include a ferromagnetic material, and in some examples, can be magnetized to act as a ferromagnet. The term “ferromagnet” is used to describe permanent magnets, or materials that can be magnetized by an external magnetic field and after removal from the magnetic field, retain the magnetism that was introduced. In accordance with examples herein, with respect to the EMI protection films, the metals and/or alloys can be magnetized to have a magnetic fluid density from about 4,000 Gauss to about 15,000 Gauss, from about 5,000 Gauss to about 13,000 Gauss, or from about 7,500 Gauss to about 12,000 Gauss.

In some examples, EMI protection film can include iron (transition metal), a nickel (transition metal), a cobalt (transition metal), a gadolinium (lanthanide series rare earth metal), or an alloy thereof. There are also other alloys that can be ferromagnetic that do not include one of these elements. With those alloys, the individual metallic elements may not be ferromagnetic as an elemental metal, but when alloyed with certain other metals or as an oxide, they can be ferromagnetic, e.g., chromium (IV) oxide and others. Thus, the ferromagnetic material can be an elemental metal, such as carbonyl iron, an alloy of elementals, an alloy of metal and semi-metal, a metal oxide, or any other material that can receive and retain a magnetic field.

Carbonyl iron, as an example of an elemental ferromagnetic material, is a highly pure form of iron with only minimal amounts of impurity. More specifically, “carbonyl iron” can be defined as a highly pure grade of iron, e.g., iron content of 97.5 atomic % (at %) to less than 99.5 at % for grade S carbonyl iron and 99.5 at % to about 99.9 at % iron for grade R carbonyl iron. Both grade S and grade R carbonyl iron are considered to be carbonyl iron in accordance with the present disclosure. Carbonyl iron can be prepared by the chemical decomposition of purified iron pentacarbonyl, and the raw material can be used to form thin metal films suitable for vacuum-release over-molding, for example. To the extent that impurities may be present in the carbonyl iron film, particularly in grade R carbonyl iron and to a lesser extent in grade S carbonyl iron, the impurities tend to be in the form of carbon, oxygen, and nitrogen.

Alloys, on the other hand, can include multiple metals from this group alloyed together and/or metals that may not be included in this group. Thus, an alloy can include a second metal (or third, fourth, etc.) can be another transition metal(s) or rare earth metal(s) of any type that may provide an alloy useful for EMI shielding properties, and/or can even include a semi-metal(s), e.g., silicon. As mentioned previously, iron is an example of an elemental metal that can be used, e.g., in the form of carbonyl metal, though even with carbonyl metal there can be impurities present in the form of carbon, oxygen, nitrogen, etc. Understanding this, impurities (which sometimes may be included intentionally as a dopant) that are not metal or semi-metal are not specifically described herein as being part of the alloys, though it is understood that they may be present in small or even trace amounts.

In further detail, more specific examples of iron alloys that can be used include iron-silicon alloy, iron-silicon-chromium alloy, iron-silicon-boron alloy, neodymium-iron-boron alloy, iron-nickel alloy, e.g., permalloy, iron-aluminum-nickel-cobalt alloy, e.g., also referred to as alcino which is Fe alloyed with Al—Ni—Co and sometimes Cu and/or Ti. Alcino is also an example of a nickel alloy as well as a cobalt alloy. Samarium and/or neodymium can also be alloyed with cobalt to provide a ferromagnetic material. Other nickel alloys that can be used that may be ferromagnetic include nickel-zinc alloy, iron-nickel alloy (mentioned above). Other materials that do not include an appreciable concentration (or any) iron, nickel, cobalt, or gadolinium, but which can be ferromagnetic, include certain oxide-based ferromagnets, e.g., chromium(IV) oxide, gallium-manganese-arsenide, manganese-zinc alloy, manganese-bismuth alloy, aluminum-copper-manganese alloy, among others. As mentioned, many of these alloys, which can include alloys of multiple transition metals, alloys of transition metals with semi-metals, e.g., silicon, alloys of transition metals with rare earth metals, or other combinations of alloys, can be ferromagnetic.

Adhesive Layers

An adhesive layer can be applied as a thin layer of adhesive to either the EMI protection film, the electronic component, or both. In one example, the adhesive can be applied to the EMI protection film prior to application to the electronic component. The adhesive layer can be a photo-curable adhesive, such as a UV-curable adhesive that can be cured using ultraviolet (UV) energy, for example. In some more specific examples, the photo-curable adhesives can be an epoxy, a polyurethane acrylate, a cyanoacrylate, or similar compound. Though the adhesive can be photo-curable, in some examples, it may not be photo-curable. That stated, photo-curable adhesives have an advantage of being environmentally friendly without traditional drying where volatile solvents evaporate into the immediate environment, as well as providing a consistent curing mechanism with often less shrinkage (solvent evaporation can lead to shrinkage due to removal of solvents). Furthermore, as the adhesive layer is between two other structures, e.g., the EMI protection layer and the electronic component, a curing mechanism that does not rely on evaporative drying can be advantageous. With specific reference to photo-curable adhesives, in one example, the UV energy can be applied to the adhesive layer after applying the EMI protection layer and the adhesive layer to the electronic component. Even though the adhesive layer is between the EMI protection layer and the electronic component, the UV energy is still effective at curing the adhesive layer because the adhesive layer is in contact with the EMI protection layer, which is thin but also includes metal, e.g., iron or other metal or metal alloy. More specifically, some photo-curable adhesives, such as UV-curable adhesives, can exhibit a secondary anaerobic cure in the presence of a metal and in the absence of oxygen, for example. Alternatively, moisture cure or a heat activated secondary cure can occur with some adhesive materials used for the adhesive layer. These types of secondary curing can be effective with applications where the area being cured may otherwise be in a shadow (relative to the UV energy source). By being covered by the EMI protection layer, and being sandwiched between the EMI protection layer and the electronic component, there may be conditions suitable for secondary anaerobic cure, or in other examples, other secondary curing can occur, such as further curing by application of heat.

The UV energy can be applied to activate the electronic component with an over-molded EMI protection layer (with the photo-curable adhesive therebetween), for example, at from about 600 mJ/cm² to about 1,500 mJ/cm², from about 700 mJ/cm² to about 1,300 mJ/cm², or from about 800 mJ/cm² to about 1,200 mJ/cm². Suitable time periods for exposure can be from about 5 seconds to about 1 minute, from about 5 seconds, to about 45 seconds, from about 10 seconds to about 30 seconds, or from about 10 seconds to about 20 seconds, for example. In some examples, heat may or may not be applied, but if applied, it can be applied at from about 80° C. to about 150° C., or from about 90° C. to about 120° C.

In further detail, the adhesive layer can act as an insulating layer between the electronic component and the EMI protection film. Thus, the adhesive layer can prevent contact from occurring between the EMI protection layer and the electronic component, which could otherwise create electrical issues with respect to unwanted conductivity between electronic components on a common substrate, for example. The adhesive layer can have an average thickness from about 5 μm to about 50 μm, from about 10 μm to about 40 μm, or from about 15 μm to about 35 μm, for example.

Release Layers

To release the EMI protection layer from a mold, such as a vacuum-release mold, the EMI protection layer can include a release layer, positioned on an opposite surface relative to the adhesive layer. The release layer can be a thin layer of a variety of materials with an adhesive strength strong enough to temporarily adhere to the EMI protection layer, but weak enough to be removed easily after over-molding the EMI protection layer onto the electronic component. Thus, in one example, the release layer can be used to separate the EMI protection layer from the over-molding mold, and in another example, the release layer can also be removable from the EMI protection layer after application to the electronic component. Example release layers can include materials of polyethylene terephthalates, polysiloxanes, e.g., polydialkylsiloxanes, orpolyalkylphenyl siloxanes, etc., and the like. The thickness of the release layer can be sufficiently thick to provide good internal strength for clean removal from the mold, but thin enough to not interfere with the over-molding process. Example thickness can be from about 3 μm to about 30 μm, from about 4 μm to about 20 μm, or from about 5 μm to about 10 μm.

Vacuum-Release Over-Molding

In the context of the present disclosure, “vacuum-release over-molding” is a process of over-molding thin films of ferromagnetic material, or EMI protection films, onto electronic components using negative vacuum pressure to receive the EMI protection film onto a mold, and then releasing the EMI protection film from the mold onto the electronic component for over-mold attachment. The release can include the application of positive pressure to the EMI protection film (opposite the electronic component). As mentioned, an adhesive layer can be included on one side of the EMI protection film to adhere the EMI protection film to the electronic components. On the other side, there can be a release layer that can be used to separate the EMI protection film from the mold, and can further be removed from the EMI protection film in some instances. Regardless, the structure of the EMI protection film becomes conformed to an outer surface of the electronic component during the molding process.

An example of vacuum-release over-molding is shown in FIGS. 2A-2C, wherein FIG. 2A shows a cross-section of an assembly of layers 200, including an EMI protection film 230, an adhesive layer 240, and a release layer 250. The cross-section is taken along section A-A of a plan view of the assembly of layers. In the plan view, only the release layer is visible, but shown in phantom lines is an outline of an area where the assembly of layers may be applied to an electronic component 220.

FIG. 2B also depicts the cross-section of the assembly of layers 200, including the EMI protection film 230, the adhesive layer 240, and the release layer 250. Also shown is an example vacuum-release over-molding apparatus 205, including a vacuum 270 fluidly coupled to a molding cavity 265 of a vacuum-release mold 260. Thus, negative pressure can be applied to the molding cavity, and thus to the assembly of layers in preparation for application to an electronic component 220 positioned on a substrate 210. In this instance, the electronic component is positioned on the substrate (without regard to relative orientation) and secured thereto by a pair of mechanical fasteners. However, it is understood that other types or numbers of fasteners can be used, adhesives can be used, or the like.

FIG. 2C depicts the cross-section of the assembly of layers 200, including the EMI protection film 230, the adhesive layer 240, and the release layer 250, after the assembly of layers has been over-molded with respect to the electronic component 220 and the substrate 210. The vacuum pressure applied by the vacuum 270 in this example is thus released, or more typically reversed to generate positive pressure into the vacuum-release mold 260 (or more precisely the molding cavity shown in FIG. 2B) to apply the assembly of layers formed in part by the mold to the layers over the electronic component 220. In addition to the mechanical force applied to the assembly of layers by the vacuum-release mold, the positive pressures that can be used can range from about 20 psi to about 150 psi, from about 30 psi to about 100 psi, or from about 40 psi to about 75 psi, for example.

Methods of Protecting Electronic Devices from EMI

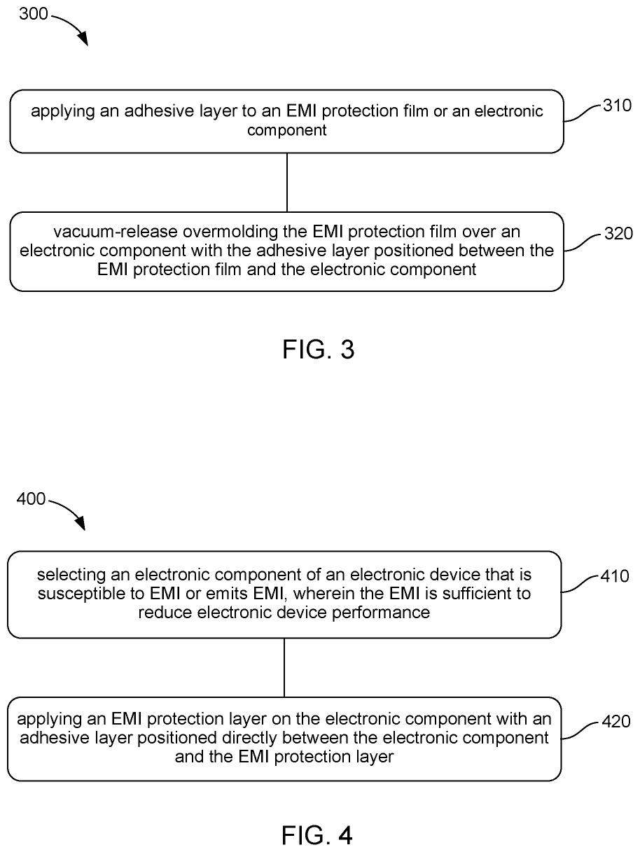

In accordance with examples of the present disclosure, a method 300 of protecting an electronic device from EMI is shown in FIG. 3. The method can include applying 310 an adhesive layer to an EMI protection film or an electronic component, and vacuum-release over-molding 320 the EMI protection film over an electronic component with the adhesive layer positioned between the EMI protection film and the electronic component. The adhesive layer can be photo-curable, for example. The photo-curable adhesive layer can be UV-curable and can be exposed to UV energy at from about 600 mJ/cm² to about 1,500 mJ/cm² for about 5 seconds to about 1 minute. Other energy levels and timings can likewise be used, depending on the adhesive selected, the thickness of the various layers, the material makeup of EMI protection layer, etc. Notably, the method of protecting an electronic device from EMI can be implemented using any of the structural and other features described herein as they relate to the electronic devices, and thus, those details are incorporated herein to the present methodology.

Methods of Reducing EMI in an Electronic Device

In accordance with other examples of the present disclosure, a method 400 of reducing EMI in an electronic device is shown in FIG. 4. The method can include identifying 410 an electronic component of an electronic device that is susceptible to EMI or emits EMI, and applying 420 an EMI protection layer on the electronic component with an adhesive layer positioned directly between the electronic component and the EMI protection layer. When selecting or identifying the electronic component that is susceptible to EMI or which emits EMI, it can be determined that EMI issues may be present if the EMI interaction is present at a sufficient level to reduce electronic device performance. Electronic device performance reduction can be either with respect to one of the electronic components directly at issue, e.g., the component(s) having the EMI protection layer applied, or with respect to the electronic device generally, e.g., resources diversion may cause another component to underperform, become damaged, etc. The EMI protection layer can be applied, for example, by vacuum-release over-molding. Notably, the method of reducing EMI in an electronic device can be implemented using any of the structural and other features described herein as they relate to the electronic devices, and thus, those details are incorporated herein to the present methodology.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if each numerical value and sub-range is explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0.2 μm to about 0.4 μm, about 0.2 μm to about 0.5 μm, about 0.1 μm to about 0.4 μm etc.

The following illustrates an example of the present disclosure. However, it is understood that the following is illustrative of the application of the principles of the present disclosure. Numerous modifications and alternative compositions, methods, devices, systems, etc., may be devised without departing from the present disclosure. The appended claims are intended to cover such modifications and arrangements.

### EXAMPLES

### Example 1—Preparation of Assembly of Layers for Vacuum-Release Over-Molding of EMI Protection Layer

An example assembly of layers including an EMI protection layer and adhesive layer is prepared as follows:
1) A neodymium-iron-boron (NdFeB) ferromagnetic material sheet having a thickness of about 0.2 mm is obtained from Arnold Magnetic Technologies (United States) and cut to a size of about 12 by 16 inches to be over-molded onto laptop electronic components.
2) To one side of the ferromagnetic sheet is applied a polyester release layer having a thickness of about 15 μm.
3) To the other side of the ferromagnetic sheet is applied a urethane-acrylate UV-curable adhesive layer at a thickness of about 15 μm.

### Example 2—Application of EMI Protection Layer to Electronic Component

An EMI protection layer is over-molded on an electronic component as follows:
1) An electronic component, namely a graphics processing unit (GPU), having dimensions of about 15 mm (l)×15 mm (w)×1.5 mm (d), which is a package of multiple discrete individual components, such as a printed circuit board, a central processing unit, and a solid-state drive, is affixed to a substrate. The substrate is a magnesium alloy (AZ31B).
2) The assembly of layers prepared in Example 1 is vacuum-release molded on the electronic component using about 50 psi of negative pressure applied to a vacuum-release mold to hold the assembly of layers against the mold, and then the mold is mechanically positioned and pressed over the electronic component where the negative pressure is released and positive pressure applied at about 70 psi. The UV-curable adhesive layer contacts the electronic component and is thus positioned between and in contact with both the electronic component and the EMI protection layer.
3) The release layer allows the mold to be removed from the over-molded EMI protection layer. The release layer is also separated from the EMI protection layer.
4) UV energy having a wavelength of about 254 nm and about 900 J/cm² is then applied to the EMI protection layer for 15 seconds. The adhesive layer becomes UV-cured through the EMI protection layer.

What has been described and illustrated herein is an example of the disclosure along with some of its variations. The terms, descriptions, and figures used herein are set forth by way of illustration and are not meant as limitations. Many variations are possible within the disclosure, which is intended to be defined by the following claims—and their equivalents—in which all terms are meant in their broadest reasonable sense unless otherwise indicated.

What is claimed is:

1. An electronic device comprising:
a substrate;
an electronic component carried by the substrate;
an EMI protection film over-molded on the electronic component, wherein the EMI protection film comprises a ferromagnetic material; and
an adhesive layer directly adhering the EMI protection film to the electronic component.

2. The electronic device of claim 1, wherein the substrate is a circuit board, an electronic device frame, or an electronic device housing; and wherein the electronic component is a battery, a printed circuit board, a central processing unit, a graphics processing unit, an integrated circuit, a piezoelectric device, a cable assembly, a semiconductor, a display chip, a memristor, an electro-mechanical device, an electro-optical device, a transducer, a sensor, a detector, an antenna, a solid-state drive, or a combination thereof.

3. The electronic device of claim 1, further comprising a second electronic component carried by the substrate, wherein the second electronic component includes a second EMI protection film over-molded on the second electronic component with an adhesive layer directly adhering the EMI protection film to the electronic component.

4. The electronic device of claim 1, wherein the EMI protection film is over-molded on the electronic component by vacuum-release over-molding.

5. The electronic device of claim 1, wherein the EMI protection film is magnetized at from 4,000 Gauss to about 15,000 Gauss.

6. The electronic device of claim 1, wherein the EMI protection film includes an iron-silicon alloy, an iron-silicon-chromium alloy, an iron-silicon-boron alloy, an oxide-based ferromagnet, a neodymium-iron-boron ferromagnet, a manganese- and zinc-based ferromagnet, a nickel- and zinc-based ferromagnet, a manganese-bismuth ferromagnet, an aluminum-copper-manganese ferromagnet, a neodymium-iron-boron ferromagnet, or a combination thereof.

7. The electronic device of claim 1, wherein the EMI protection film has an average thickness from about 0.05 mm to about 0.35 mm, and the adhesive layer has a thickness from about 5 μm to about 50 μm.

8. The electronic device of claim 1, wherein the adhesive layer provides a layer of insulation between the EMI protection film and the electronic component.

9. The electronic device of claim 1, wherein the adhesive layer is photo-cured between the EMI protection layer and the electronic component.

10. An electronic device of claim 1, wherein the electronic component includes an EMI susceptible portion, an EMI emitting portion, or both on a common substrate, and the EMI protection film is applied to the EMI susceptible portion, the EMI emitting portion, or both.

11. The electronic device of claim 1, wherein the EMI protection film is applied is also applied to the substrate.

12. A method of protecting an electronic device from EMI comprising:
applying an adhesive layer to an EMI protection film or an electronic component; and
vacuum-release over-molding the EMI protection film over an electronic component with the adhesive layer positioned between the EMI protection film and the electronic component.

13. The method of claim 12, wherein the adhesive layer includes is photo-curable, and the adhesive layer is exposed to UV energy at from about 600 mJ/cm² to about 1,500 mJ/cm² for about 5 seconds to about 1 minute.

14. A method of reducing EMI in an electronic device, comprising:
selecting an electronic component of an electronic device that is susceptible to EMI or emits EMI, wherein the EMI is sufficient to reduce electronic device performance; and
applying an EMI protection layer on the electronic component with an adhesive layer positioned directly between the electronic component and the EMI protection layer.

15. The method of claim 14, wherein applying is by vacuum-release over-molding.
